(19) United States
(12) Patent Application Publication
(10) Pub. No.: US 2018/0284040 A1
(43) Pub. Date: Oct. 4, 2018

(54) METHOD OF OBSERVING ORGANIC SPECIMEN, AND OBSERVATION HOLDER AND OBSERVATION STAGE USED THEREIN

(71) Applicant: NATIONAL INSTITUTE OF ADVANCED INDUSTRIAL SCIENCE AND TECHNOLOGY, Chiyoda-ku (JP)

(72) Inventor: Toshihiko OGURA, Ibaraki (JP)

(73) Assignee: NATIONAL INSTITUTE OF ADVANCED INDUSTRIAL SCIENCE AND TECHNOLOGY, Chiyoda-ku (JP)

(21) Appl. No.: 15/765,789

(22) PCT Filed: Oct. 11, 2016
(86) PCT No.: PCT/JP2016/080111

§ 371 Date: Apr. 4, 2018

(30) Foreign Application Priority Data
Oct. 16, 2015 (JP) 2015-204931

(51) Int. Cl. G01N 23/2251; G01N 27/00; H01J 37/20; H01J 37/28

(52) U.S. Cl. CPC G01N 23/2251; G01N 27/00; G01N 2223/418; H01J 37/28; G01N 2223/309; H01J 37/20

(57) ABSTRACT

The invention provides a method of observing an organism or any other organic specimen in an aqueous solution in a scanning electron microscope. The method includes placing the organic specimen along with the aqueous solution between opposing surfaces of a pair of first and second insulating thin films facing each other, irradiating and scanning an electrically conductive thin film provided on an outward facing surface of the first insulating thin film with a pulsed electron beam an intensity of which is changed in a form of pulses, and acquiring an image according to a change in electric potential of an outward facing surface of the second insulating thin film, in which the composition of the specimen is analyzed based on the difference between the images corresponding to the pulsed electron beam applied at different ON/OFF frequencies.

### TECHNICAL FIELD

The present invention relates to a method of observing an organic specimen in a scanning electron microscope and an observation holder and an observation stage used in the method, and particularly to an organic specimen observation method that allows observation of a living organism in an aqueous solution as the organic specimen and an observation holder and an observation state used in the method.

### BACKGROUND ART

To observe an organic specimen by using a scanning electron microscope in related art, the specimen is mounted, for example, with paraformaldehyde and then so processed in a variety of manners that damage on the specimen due to the electron beam is suppressed and a high-contrast image is produced. For example, it is known to use a method of coating gold, platinum, carbon, or any other substance on the surface of a specimen, a method of dying a specimen with a heavy metal, or other methods. On the other hand, there has been a proposed observation method that allows generation of a high-contrast image without any of the cumbersome processes described above.

For example, Patent Literature 1 discloses that a laminate of an insulating thin film/electrically conductive thin film is provided, and a biological specimen is attached onto the electrically conductive thin film, and that when the insulating thin film side is irradiated with an electron beam, a tunnel effect produced by a large electric potential gradient in the laminate moves secondary electrons produced in the insulating thin film toward the electrically conductive thin film side, and the secondary electrons also pass through the biological specimen. Patent Literature 1 states that sensing the spatial distribution of the transmitted electrons (tunneling electrons) allows observation of the internal structure of the biological specimen.

Further, Non Patent Literatures 1 to 3 each disclose a method of observing a biological specimen in an aqueous solution in a scanning electron microscope. When a metal thin film is formed on an insulating thin film and is irradiated with an electron beam, the electric potential of the films locally changes, and the electric potential change attenuated when it passes through the biological specimen can be observed in the form of an image (varying electric potential transmissive observation). The method uses the fact that water has high relative dielectric constant of about 80 and therefore easily transmits an electric potential change, whereas a biological specimen has low relative dielectric constant of about 2 to 3 and therefore hardly transmits an electric potential change.

Patent Literature 2 discloses that as a method of observing a biological specimen in an aqueous solution in a scanning electron microscope, the biological specimen along with the aqueous solution is interposed between a pair of an insulating thin film and an electrically conductive thin film that face each other. In the method, a secondary electron emission prevention thin film is provided on the insulating thin film and irradiated with the electron beam. Many of the secondary electrons produced in the secondary electron emission prevention thin film flow into the insulating thin film, and a steep electric potential gradient is therefore formed between the insulating thin film and the electrically conductive thin film that is negatively charged and faces the insulating thin film.

Further, Patent Literature 3 similarly discloses, as a method of observing a biological specimen in an aqueous solution in a scanning electron microscope, an observation method including causing a biological specimen along with the aqueous solution to be interposed between a pair of insulating thin films facing each other, scanning and irradiating an electrically conductive thin film provided on the outward facing surface of one of the insulating thin films with the electron beam with the intensity thereof changed in the form of pulses, and sensing a change in electric potential of the outward facing surface of the other insulating thin film.

### CITATION LIST

### Patent Literature

Patent Literature 1: Japanese Patent Laid-Open No. 2013-134952

Patent Literature 2: Japanese Patent Laid-Open No. 2014-22323

Patent Literature 3: Japanese Patent Laid-Open No. 2014-203733

### Non Patent Literature

Non Patent Literature 1: T. Ogura, “Direct observation of unstained biological specimens in water by the frequency transmission electric-field method using SEM”, PLOS ONE Vol. 9, e92780(6 pp) (2014)

Non Patent Literature 2: T. Ogura, “Non-destructive observation of intact bacteria and viruses in water by the highly sensitive frequency transmission electric-field method based on SEM”, Biochem. Biophys. Res. Commun., Vol. 450, p. 1684-1689 (2014)

Non Patent Literature 3: T. Ogura, “Nanoscale analysis of unstained specimens in water without radiation damage using high-resolution frequency transmission electric-field system based on FE-SEM”, Biochem. Biophys. Res. Commun., Vol. 459, p. 521-528 (2015)

### SUMMARY OF INVENTION

### Technical Problem

According to the observation method disclosed in Patent Literature 3 described above, a living biological specimen in an aqueous solution can be directly observed in a scanning electron microscope because the biological specimen is not directly irradiated with the electron beam. Further, since the resolution of an image roughly depends on the diameter of the radiated electron beam, reducing the diameter to about 1 nm allows 1-nm resolution roughly equal to the diameter of the electron beam. That is, a biological specimen containing bacteria, viruses, proteins, or a protein complex can also be observed.

The present invention has been made in view of the circumstances described above. An object of the present invention is to provide an observation method that allows higher-resolution observation of a living biological specimen in an aqueous solution in a scanning electron microscope and further allows analysis of the composition of the biological specimen. Another object of the present invention is to provide an observation holder and an observation state used in the observation method.

### Solution to Problem

A method of observing an organism or any other organic specimen in an aqueous solution in a scanning electron microscope according to the present invention includes placing the organic specimen along with the aqueous solution between opposing surfaces of a pair of first and second insulating thin films facing each other, irradiating and scanning an electrically conductive thin film provided on an outward facing surface of the first insulating thin film with a pulsed electron beam an intensity of which is changed in a form of pulses, and acquiring an image according to a change in electric potential of an outward facing surface of the second insulating thin film, in which composition of the specimen is analyzed based on a difference between the images corresponding to the pulsed electron beam applied at different ON/OFF frequencies.

The invention described above allows higher-resolution observation of a living biological specimen in an aqueous solution in a scanning electron microscope and analysis of the composition of the biological specimen to be plainly performed based on the difference between images produced by the different ON/OFF frequencies.

In the invention described above, the pulsed electron beam may be so controlled that a group of pulses repeated at a first ON/OFF frequency are repeated at a second ON/OFF frequency. The invention described above allows higher-resolution observation of a living biological specimen in an aqueous solution in a scanning electron microscope and also analysis of the composition of the biological specimen to be performed in a simpler, quicker manner.

In the invention described above, an electret layer may be disposed between the first insulating thin film and the electrically conductive thin film. The invention described above allows higher-resolution, clearer observation of a living biological specimen in an aqueous solution in a scanning electron microscope.

In the invention described above, an electric potential sensitive film made of an electric potential sensitive substance that causes an optical change in response to an electric potential change may be provided on an outward facing surface of the second insulating thin film, and the optical change is optically sensed. Further, in the invention described above, the optical change of the electric potential sensitive film may be sensed in synchronization with the electron beam with which the electrically conductive thin film is scanned and irradiated. The invention described above allows direct, higher-resolution observation of a living biological specimen in an aqueous solution in a scanning electron microscope.

An observation holder according to the present invention for observing an organism or any other organic specimen in an aqueous solution in a scanning electron microscope is used with a method including placing the organic specimen along with the aqueous solution between opposing surfaces of a pair of first and second insulating thin films facing each other, irradiating and scanning an electrically conductive thin film provided on an outward facing surface of the first insulating thin film with a pulsed electron beam an intensity of which is changed in a form of pulses, and acquiring an image according to a change in electric potential of an outward facing surface of the second insulating thin film, and the observation holder includes at least a specimen holding space where the organic specimen is held along with the aqueous solution, the first and second insulating thin films that form the specimen holding space, the electrically conductive thin film provided on the outward facing surface of the first insulating thin film, and an electric potential sensitive film made of an electric potential sensitive substance and provided on an outward facing surface of the second insulating thin film.

The invention described above allows clearer, higher-resolution observation of a living biological specimen in an aqueous solution in a scanning electron microscope.

In the invention described above, the electric potential sensitive substance causes an optical change in response to an electric potential change. The invention described above allows clearer, higher-resolution observation of a living biological specimen in an aqueous solution in a scanning electron microscope.

In the invention described above, an electret layer is disposed between the first insulating thin film and the electrically conductive thin film. The invention described above allows clearer, higher-resolution observation of a living biological specimen in an aqueous solution in a scanning electron microscope.

An observation stage according to the present invention for observing an organism or any other organic specimen in an aqueous solution in a scanning electron microscope is used with a method including placing the organic specimen along with the aqueous solution between opposing surfaces of a pair of first and second insulating thin films facing each other, irradiating and scanning an electrically conductive thin film provided on an outward facing surface of the first insulating thin film with a pulsed electron beam an intensity of which is changed in a form of pulses, and acquiring an image according to a change in electric potential of an outward facing surface of the second insulating thin film, and the observation stage includes at least sensing means for sensing the change in electric potential of the outward facing surface of the second insulating thin film.

The invention described above allows higher-resolution observation of a living biological specimen in an aqueous solution in a scanning electron microscope.

In the invention described above, the sensing means is means for optically sensing a change in an electric potential sensitive film made of an electric potential sensitive substance that causes an optical change in response to the change in electric potential of the outward facing surface of the second insulating thin film. The invention described above allows direct, higher-resolution observation of a living biological specimen in an aqueous solution in a scanning electron microscope.

### BRIEF DESCRIPTION OF THE DRAWINGS

FIG. 1 is a block diagram showing an observation method according to the present invention.

FIG. 2 is a cross-sectional view of key parts in a scanning electron microscope with which the observation method according to the present invention is used.

FIG. 3 shows an example of a control signal from a function generator.

FIG. 4 describes analysis of images based on a change in electric potential.

FIG. 5 is a cross-sectional view of key parts in a scanning electron microscope with which the observation method according to the present invention is used.

FIG. 6 is a cross-sectional view of key parts in a scanning electron microscope with which the observation method according to the present invention is used.

FIG. 7 describes concentration of a change in electric potential.

### DESCRIPTION OF EMBODIMENTS

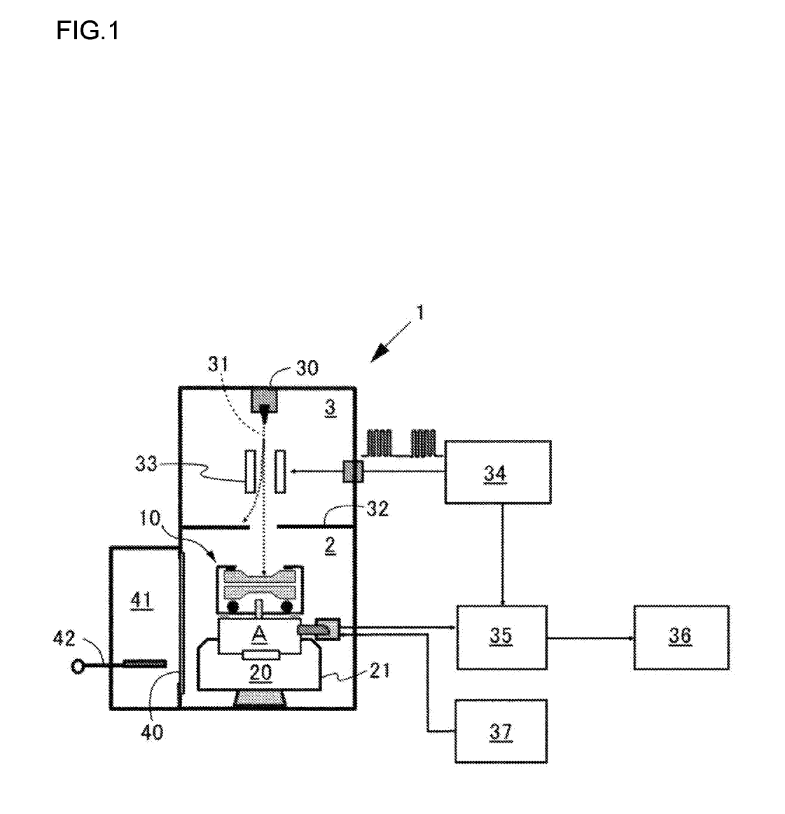

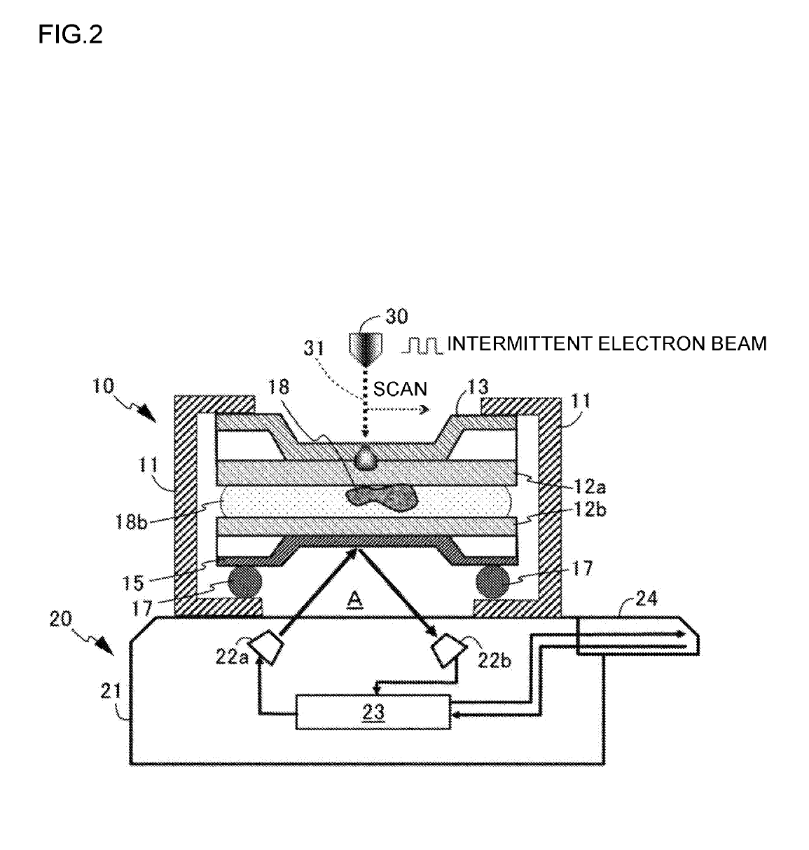

An embodiment of an observation method and apparatus according to the present invention for observation of a biological specimen in an aqueous solution in a scanning electron microscope will be described below with reference to FIGS. 1 and 2.

A scanning electron microscope 1 is an apparatus that includes a specimen chamber 2, which can be evacuated to a predetermined degree of vacuum, and causes an electron beam 31 from an electron source 30 in the vicinity of the top of an enclosure 3, which communicates with the specimen chamber 2 and is located thereabove, to as appropriate pass through an aperture 32 and guides the electron beam 31 to a predetermined position on an observation holder 10 in the specimen chamber 2, as shown in FIG. 1.

The electron source 30 is a field-emission-type electron gun. The travel direction of the radiated electron beam 31 can be changed by a polarizer 33, and an ON/OFF signal outputted from a function generator 34 and having a frequency of, for example, at least 1 kHz in conjunction with a rectangular-waveform control signal may cause the electron beam having power that changes in the form of pulses corresponding to the control signal to be incident on the observation holder 10.

The specimen chamber 2 is provided with a specimen exchange compartment 41 with an openable/closable shutter 40 provided therebetween, and a specimen exchange rod 42 can be used to attach and detach the observation holder 10 to and from a stage 20 provided in the specimen chamber 2 with the degree of vacuum in the specimen chamber 2 maintained. An optical measurement system A, which will be described later, is provided on an insulating enclosure 21, which encloses the stage 20, and a signal from the optical measurement system A can be extracted out of the specimen chamber 2. The signal is amplified by an amplifier 23 (see FIG. 2) built in the optical measurement system A, guided to a frequency separator 35, where the signal undergoes frequency separation, and the resultant signal is outputted to a composition analyzer 36. The frequency separator 35 receives, from the function generator 34, a reference signal that serves as a reference of a change in the power of the electron beam described above. A DC power supply 37 for operating the amplifier 23 and other components is connected to the optical measurement system A.

The observation holder 10 includes an outer frame 11, which has upper and lower windows, and insulating thin films 12a and 12b, which internally close the upper and lower windows, respectively, as shown in FIG. 2. The insulating thin film 12a, which closes the upper window, is so placed above an aqueous solution 18b containing a biological specimen 18 that the lower surface of the insulating thin film 12a holds the aqueous solution 18b, and an electrically conductive thin film 13 is layered on the upper surface of the insulating thin film 12a. The insulating thin film 12b, which closes the lower window, is so placed below the aqueous solution 18b containing the biological specimen 18 that the upper surface of the insulating thin film 12b holds the aqueous solution 18b, and a coating made of electric potential sensitive ink is layered as an electric potential sensitive film 15 on the lower surface of the insulating thin film 12b.

The electric potential sensitive substance that forms the electric potential sensitive film 15 is preferably barium titanate or lead zirconate titanate, each of which is a piezoelectric material, polyvinylidene fluoride, which is a piezoelectric polymer. A film made of any of the electric potential sensitive substances described above behaves in such a way that a change in electric potential of the film changes the thickness of the film, changes the reflectance and absorbance of light with which the film is irradiated, and changes the phase of the light. Detection of any of the changes described above allows highly sensitive detection of the change in the electric potential.

The insulating thin films 12a and 12b are each in contact with the inner surface of the observation holder 10 via an O ring 17 or a gasket or any other component that is not shown, so that the interior of the observation holder 10 can be sealed against the vacuum in the exterior thereof, whereby the internal atmospheric pressure can be maintained. The insulating thin films 12a and 12b are strong enough to withstand the difference in pressure between the interior and the exterior of the observation holder 10. The other features of the observation holder 10 are known and are therefore not described in detail, and the details of the observation holder 10 are, for example, the same as those of the “specimen holder” disclosed in Patent Literature 3.

The optical measurement system A above the stage 20 includes a laser diode 22a, which is connected to the amplifier 23 and outputs a laser beam with which the electric potential sensitive film 15 can be irradiated, and a photodiode 22b, which receives the laser beam reflected off the electric potential sensitive film 15. The photodiode 22b is connected to the amplifier 23. The amplifier 23 can amplify a signal based on the reflected light received with the photodiode 22b and output the amplified signal to the frequency separator 35, as described above, via a connector 24. The amplifier 23 is connected to the DC power supply 37, which is a power supply that operates the amplifier 23 as described above, via the connector 24.

A method of using the scanning electron microscope 1 will next be described with reference to FIGS. 1 to 4.

Referring to FIG. 1, in the scanning electron microscope 1 to which the observation holder 10 is attached, after the specimen chamber 2 is evacuated to a predetermined degree of vacuum, the electron source 30 emits the electron beam 31. The power of the electron beam 31 is changed in the form of pulses by the control signal from the function generator 34.

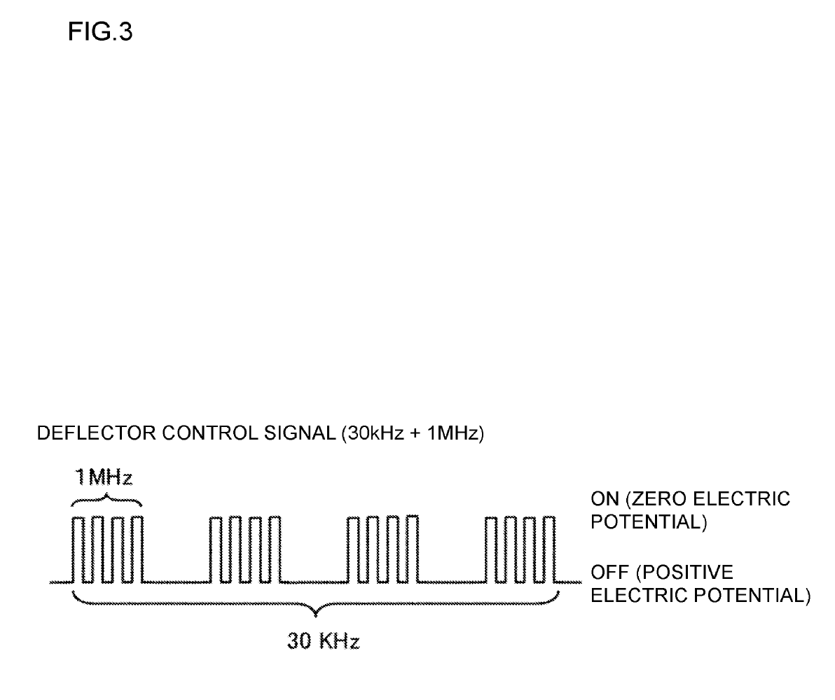

Referring also to FIG. 3, the control signal from the function generator 34 provides the polarizer 33 with groups each formed of a predetermined number of pulses that are rectangular-wave ON/OFF signals repeated at a first frequency that is a relatively high frequency, and the pulse groups are applied at a second frequency that is a relatively low frequency. In the description, the first frequency is set at 1 MHz, and the second frequency is set as 30 kHz. When the function generator 34 outputs the OFF signal, a positive-electric-potential control signal is applied to the polarizer 33. As a result, the polarizer 33 changes the travel direction of the electron beam 31, and the resultant electron beam 31 is blocked by the aperture 32 and is therefore turned off. When the function generator 34 outputs the ON signal, a zero-electric-potential control signal is applied to the polarizer 33. As a result, the polarizer 33 does not change the travel direction of the electron beam 31, and the electron beam 31 travels straight, passes through the aperture 32, and is therefore turned on. The observation holder 10 is therefore irradiated with the electron beam 31 in the form of the ON/OFF pulses repeated at the frequency synchronized with the control signal produced by the function generator 34. That is, the electron beam 31 is radiated toward the observation holder 10 in the form of the pulses so configured that the groups each formed of the predetermined number of pulses repeated at the first frequency are turned on and off at the second frequency.

Referring back to FIG. 2, the electron beam 31 radiated toward the observation holder 10 is incident through one of the windows of the observation holder 10 on the electrically conductive thin film 13 and absorbed thereby, and the portion on which the electron beam 31 is incident is negatively charged. Electric charge is therefore produced on the insulating thin film 12b, which faces the electrically conductive thin film 13, in accordance with the dielectric constants of the biological specimen 18 and the aqueous solution 18b. The aqueous solution 18b has a high dielectric constant because the water molecules therein are polarized, whereas the biological specimen 18, which is formed, for example, of proteins, has a relatively low dielectric constant. That is, the dielectric constants of the biological specimen 18 and the aqueous solution 18b corresponding to the position scanned with the electron beam 31 produce time-varying electric charge on the insulating thin film 12b. The electric potential sensitive film 15, which is a coating layered on the insulating thin film 12b, is characterized in that the color thereof changes in accordance with the change in the electric potential thereof, and the optical system A measures the change in the color and outputs a signal representing the change to the frequency separator 35. Based, for example, on the light reflected off the electric potential sensitive film 15, the optical system A can measure reflectivity, absorbance, and phase change of the reflected light. Instead, the electric potential sensitive film 15 may be so scanned with the laser beam emitted from the laser diode 22a in the optical system A that the measurement position on the electric potential sensitive film 15 corresponds to the position where the electric potential sensitive film 15 is scanned with the electron beam 31.

Referring back to FIG. 1 again, the frequency separator 35 can extract and separate, from the received signal, only the first and second frequencies of the control signal produced by the function generator 34, that is, the two frequency components of the ON/OFF pulses of the electron beam 31 with which the observation holder 10 is irradiated, based on the reference signal received from the function generator 34. The separation can be performed by using a known method, such as Fourier transform analysis. The thus extracted signals based on a change in the color of the electric potential sensitive film 15 allow the composition analyzer 36 to produce an image based on the distribution of the electric potential that has passed through the biological specimen 18 in accordance with the dielectric constant thereof and is distributed in the direction along the principal surface of the insulating thin film 12b, that is, a two-dimensional image of the distribution of the electric potential having passed through the biological specimen 18.

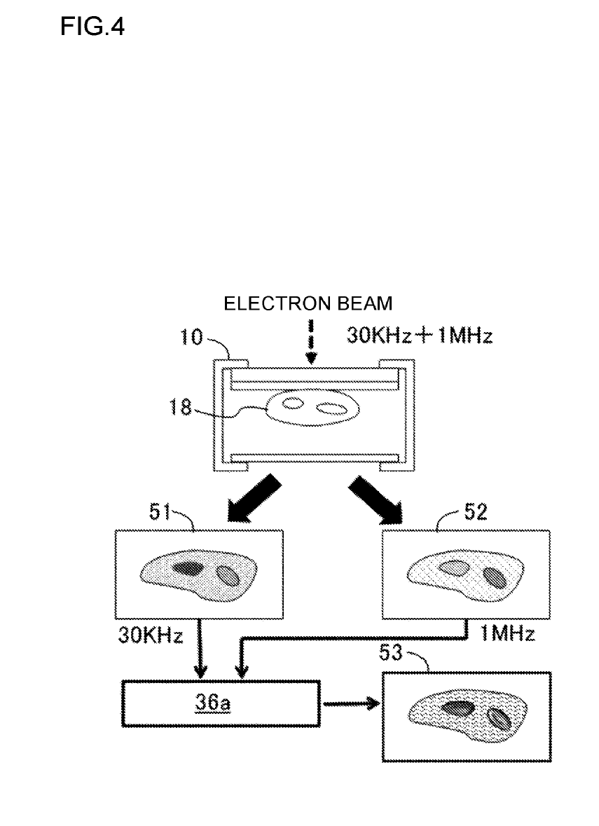

Referring to FIG. 4, the composition analyzer 36 causes an analysis section 36a to analyze electric potential distribution images 51 and 52 produced for each of the first and second frequencies in accordance with a predetermined analysis algorithm. It is known that the dielectric constant of a substance changes in accordance with the modulating frequency component and the state of the change varies on a substance basis. The composition of a substance that forms the biological specimen 18 can therefore be analyzed and identified from the state of the change in the dielectric constant based on the difference between the electric potential distribution images produced from the two frequency components. An image 53 based on the identified composition can also be produced.

In the present embodiment, the electron beam 31, which is the combination of the two frequency components, is used, and the detection signal is separated into a plurality of frequency signal components, from which images are produced. The electric potential distribution images 51 and 52 produced from the two frequency components can therefore be produced in one measurement action. Further, there is no discrepancy in time between the images to be compared with each other. It is noted that three or more frequencies may be mixed with one another to similarly produce electric potential distribution images and the images may be analyzed.

The laser beam from the laser diode 22a in the optical system A can be focused into a spot having a diameter of several micrometers at the minimum, whereby the electric potential distribution images 51 and 52 can be produced at a high resolution of several micrometers.

The detection system using the laser diode 22a has improved responsiveness, allows detection of an electric potential change that occurs at several MHz or higher with no delay corresponding to the time constant determined by a circuit capacity component, and is therefore suitable for detection of a high-frequency signal. Further, the laser beam detection method can provide many pieces of information, such as the optical intensity, deflection, and phase, and can greatly improve the sensitivity of the detection.

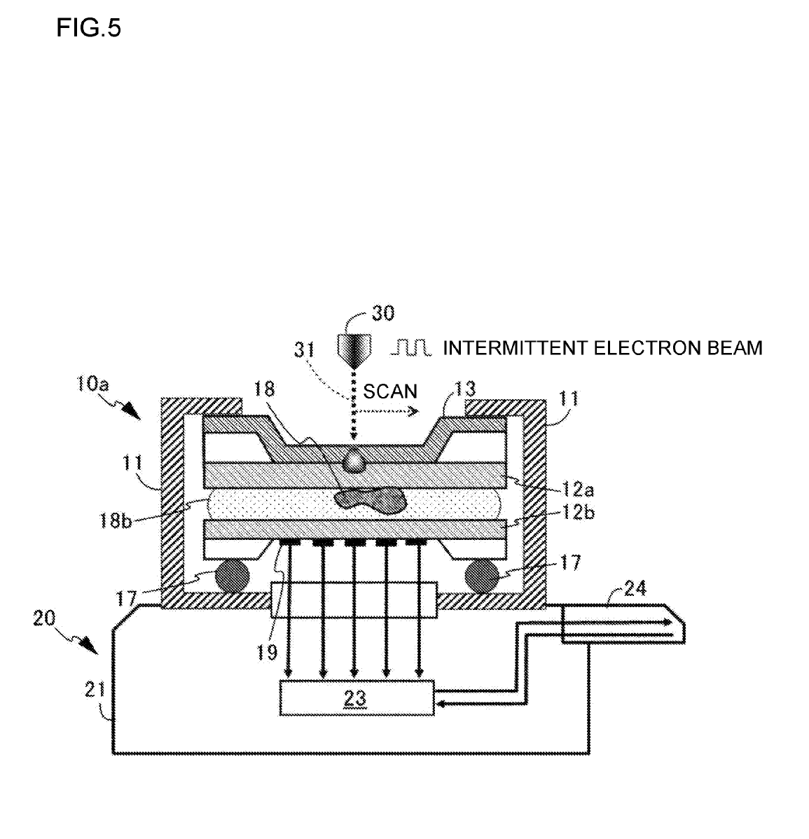

It is conceivable to employ an observation holder 10a, in which an electrode pattern 19 is attached to the lower surface of the insulating thin film 12b, and a change in electric potential thereof is measured along the electrode pattern 19, as shown in FIG. 5. That is, the electrode pattern 19 is formed of electrodes having a pattern of a plurality of metal pieces disposed along the principal surface of the insulating thin film 12b, and the metal pieces are each connected as an electrode to the amplifier 23 and allow measurement of the electric potential of the insulating thin film 12b in the position where the metal piece is disposed.

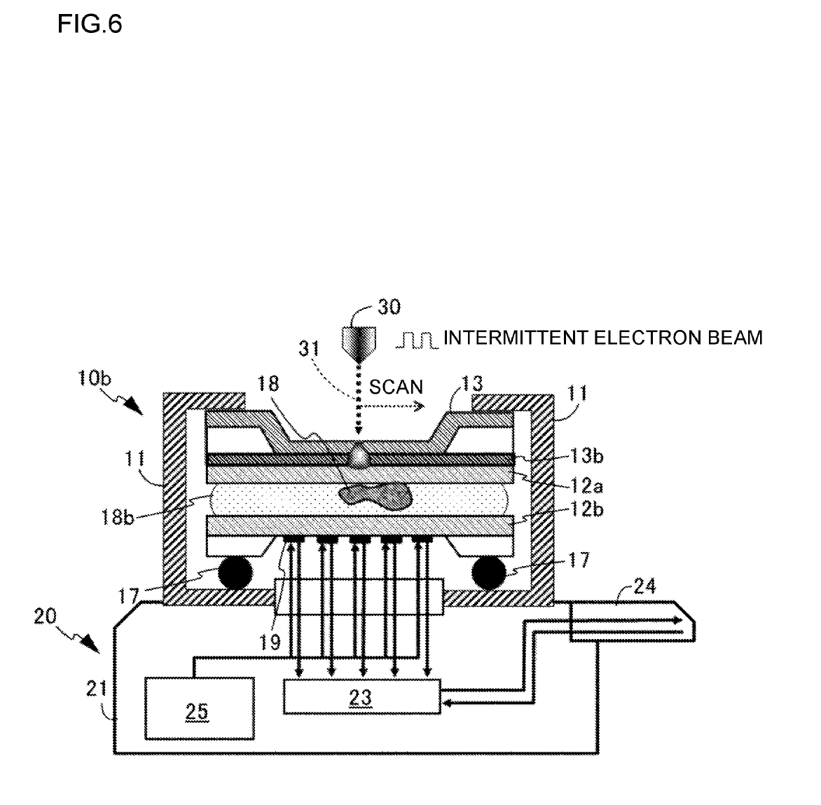

Further, it is conceivable to employ an observation holder 10b, in which an electret layer 13b formed of an electret may be provided between the insulating thin film 12a and the electrically conductive thin film 13, as shown in FIG. 6. In this case, the electric charge on the insulating thin film 12a can be homogenized in the principal plane thereof, whereby the electric potential between the insulating thin films 12a and 12b can be stabilized.

The metal pieces that form the electrode pattern 19 may each be connected also to a voltage control amplifier 25, and the voltage control amplifier 25 may manipulate the electric potential of each of the metal pieces to control the electric field applied to the insulating thin film 12b. The electric field applied to the biological specimen 18 and the aqueous solution 18b can therefore be so controlled that a change in the electric potential resulting from the electron beam 31 occurs in a more concentrated manner for higher resolution.

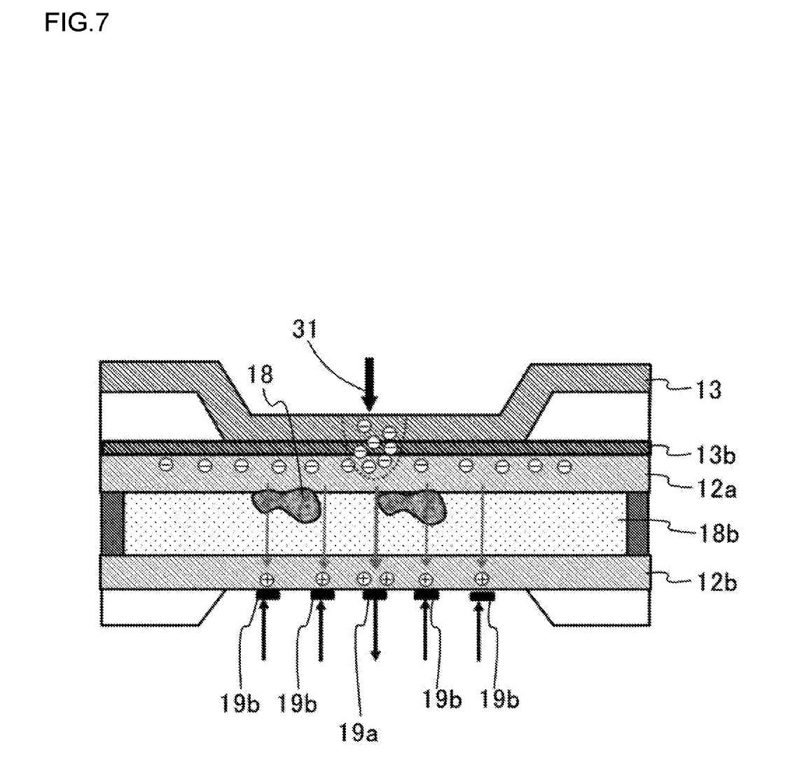

For example, out of the metal pieces that form the electrode pattern 19, only a central metal piece 19a is used as an input electrode, and positive electric potential is applied to the other metal pieces 19b, as shown in FIG. 7. As a result, a change in the electric potential resulting from the electron beam 31 is allowed to concentrate in the central metal piece 19a. The metal piece that allows an electric potential change to occur in a concentrated manner can be changed to another in accordance with the position scanned with the electron beam 31.

As described above, the present embodiment allows a biological specimen in the aqueous solution 18b to be readily observed without dying or mounting the biological specimen. In particular, no electron beam 31 passes through the biological specimen 18, or the biological specimen 18 experiences no change in pressure but is intact in the aqueous solution 18b. The biological specimen 18 only receives a change in electric potential and can therefore be observed as a living specimen. Further, the resolution can be improved by selection and combination of the embodiments described above. As a result, the composition of the biological specimen 18 can be analyzed as described above, and three-dimensional structure analysis can also be performed.

The embodiments and variations of the present invention have been described above, but the present invention is not necessarily limited thereto, and a skilled in the art may be able to conceive of a variety of other alternative embodiments and improved embodiments without departing from the substance of the present invention or the scope of the appended claims.

### REFERENCE SIGNS LIST

1 Scanning electron microscope
10 Observation holder
12a Insulating thin film
12b Insulating thin film
13 Electrically conductive thin film
15 Electric potential sensitive film
18 Biological specimen
18b Aqueous solution
31 Electron beam

1. A method of observing an organism or any other organic specimen in an aqueous solution in a scanning electron microscope, the method comprising:
placing the organic specimen along with the aqueous solution between opposing surfaces of a pair of first and second insulating thin films facing each other;
irradiating and scanning an electrically conductive thin film provided on an outward facing surface of the first insulating thin film with a pulsed electron beam an intensity of which is changed in a form of pulses; and
acquiring an image according to a change in electric potential of an outward facing surface of the second insulating thin film, wherein
composition of the organic specimen is analyzed based on a difference between the images corresponding to the pulsed electron beam applied at different ON/OFF frequencies.

2. The method of observing an organic specimen according to claim 1, wherein the pulsed electron beam is so controlled that a group of pulses repeated at a first ON/OFF frequency are repeated at a second ON/OFF frequency.

3. The method of observing an organic specimen according to claim 2, wherein an electret layer is disposed between the first insulating thin film and the electrically conductive thin film.

4. The method of observing an organic specimen according to claim 2, wherein an electric potential sensitive film made of an electric potential sensitive substance that causes an optical change in response to an electric potential change is provided on an outward facing surface of the second insulating thin film, and the optical change is optically sensed.

5. The method of observing an organic specimen according to claim 4, wherein the optical change of the electric potential sensitive film is sensed in synchronization with the electron beam with which the electrically conductive thin film is scanned and irradiated.

6. An observation holder for observing an organism or any other organic specimen in an aqueous solution in a scanning electron microscope, wherein
the observation holder is used with a method including placing the specimen along with the aqueous solution between opposing surfaces of a pair of first and second insulating thin films facing each other, irradiating and scanning an electrically conductive thin film provided on an outward facing surface of the first insulating thin film with a pulsed electron beam an intensity of which is changed in a form of pulses, and acquiring an image according to a change in electric potential of an outward facing surface of the second insulating thin film, and
the observation holder comprises at least:
a specimen holding space where the organic specimen is held along with the aqueous solution;
the first and second insulating thin films that form the specimen holding space;
the electrically conductive thin film provided on the outward facing surface of the first insulating thin film; and
an electric potential sensitive film made of an electric potential sensitive substance and provided on an outward facing surface of the second insulating thin film.

7. The observation holder according to claim 6, wherein the electric potential sensitive substance causes an optical change in response to an electric potential change.

8. The observation holder according to claim 7, wherein an electret layer is disposed between the first insulating thin film and the electrically conductive thin film.

9. An observation stage for observing an organism or any other organic specimen in an aqueous solution in a scanning electron microscope, wherein
the observation stage is used with a method including placing the organic specimen along with the aqueous solution between opposing surfaces of a pair of first and second insulating thin films facing each other, irradiating and scanning an electrically conductive thin film provided on an outward facing surface of the first insulating thin film with a pulsed electron beam an intensity of which is changed in a form of pulses, and acquiring an image according to a change in electric potential of an outward facing surface of the second insulating thin film, and
the observation stage includes at least sensing means for sensing the change in electric potential of the outward facing surface of the second insulating thin film.

10. The observation stage according to claim 9, wherein the sensing means is means for optically sensing a change in an electric potential sensitive film made of an electric potential sensitive substance that causes an optical change in response to the change in electric potential of the outward facing surface of the second insulating thin film.
